(19) United States
(12) Patent Application Publication
(10) Pub. No.: US 2026/0047439 A1
(43) Pub. Date: Feb. 12, 2026

(54) DISPLAY MODULE AND DISPLAY APPARATUS

(71) Applicant: Shanghai Tianma Microelectronics Co., Ltd., Shanghai (CN)

(72) Inventors: Shouzheng WU, Shanghai (CN); Yongxin HE, Shanghai (CN); Jujian FU, Shanghai (CN); Yuan DING, Shanghai (CN); Zhenyu JIA, Shanghai (CN)

(73) Assignee: Shanghai Tianma Microelectronics Co., Ltd., Shanghai (CN)

(21) Appl. No.: 18/950,208

(22) Filed: Nov. 18, 2024

(30) Foreign Application Priority Data
Aug. 28, 2024 (CN) 202411198611.1

(51) Int. Cl. H01L 23/60; H01L 25/075

(52) U.S. Cl. CPC H01L 23/60; H01L 25/0753

(57) ABSTRACT

The present application discloses a display module and a display apparatus. The display module includes: a substrate, an electrostatic structure, and at least one conductive pad setting region. The substrate includes a first main surface, and a second main surface opposite to the first main surface. The electrostatic structure disposed on the first main surface. The at least one conductive pad setting region is disposed on the second main surface and the conductive pad setting region includes at least one conductive pad coupled to the electrostatic structure.

### CROSS-REFERENCE TO RELATED APPLICATION

This application claims priority to Chinese Patent Application No. 202411198611.1, filed on Aug. 28, 2024, which is hereby incorporated by reference in its entirety.

### TECHNICAL FIELD

The present application relates to the field of display technology, and in particular to a display module and a display apparatus.

### BACKGROUND

In the display module of the prior art, in order to reduce the frame area of the display panel, the design space and wiring space of the electrostatic circuit are compressed, resulting in fewer electrostatic circuits and poor electrostatic protection performance of the display module as a whole.

### SUMMARY

Embodiments of the present application provide a display module and a display apparatus, which timely introduces static electricity into a conductive pad located on a second main surface through an electrostatic structure located on a first main surface, thereby improving the ability of the display panel to protect against static electricity and preventing static electricity from being introduced into various wirings and driving devices within the display panel and affecting the performance of the display panel.

In first aspect, embodiments of the present application provide a display module including: a substrate comprising a first main surface, and a second main surface opposite to the first main surface; an electrostatic structure disposed on the first main surface; and at least one conductive pad setting region disposed on the second main surface and comprising at least one conductive pad coupled to the electrostatic structure.

In second aspect, embodiments of the present application provide a display apparatus including the display module in first aspect.

### BRIEF DESCRIPTION OF THE DRAWINGS

In order to more clearly illustrate the technical solutions of embodiments of the present application, a brief description will be given below with reference to the need to be used in the embodiments of the present application. It is obvious that the drawings described below are only some embodiments of the present application, and for a person skilled in the art, other drawings can be obtained according to these drawings without involving any inventive effort.

FIG. 1 is a structural schematic view of a first main surface of a substrate according to an embodiment of the present application.

FIG. 2 is a structural schematic view of a second main surface of a substrate according to an embodiment of the present application.

FIG. 3 is a structural schematic view of a first main surface of a substrate according to another embodiment of the present application.

FIG. 4 is a cross-sectional schematic view of FIG. 3 along a line B-B′.

FIG. 5 is a structural schematic view of a conductive bracket structure according to an embodiment of the present application.

FIG. 6 is a cross-sectional schematic view of FIG. 2 along a line C-C′.

FIG. 7 is a cross-sectional schematic view of a display module according to an embodiment of the present application.

FIG. 8 is a cross-sectional schematic view of a display module according to another embodiment of the present application.

FIG. 9 is a cross-sectional schematic view of a display module according to yet another embodiment of the present application.

FIG. 10 is a cross-sectional schematic view of a display module according to still yet another embodiment of the present application.

FIG. 11 is a structural schematic view of a side surface of a substrate according to an embodiment of the present application.

FIG. 12 is a structural schematic view of a side surface of a substrate according to another embodiment of the present application.

FIG. 13 is a structural schematic view of a side surface of a substrate according to yet another embodiment of the present application.

FIG. 14 is a cross-sectional schematic view of a side surface of a substrate according to yet another embodiment of the present application.

FIG. 15 is a structural schematic view of a side surface of a substrate according to still yet another embodiment of the present application.

FIG. 16 is a cross-sectional schematic view of a display module according to even still yet another embodiment of the present application.

FIG. 17 is a structural schematic view of a second main surface of a substrate according to another embodiment of the present application.

FIG. 18 is a structural schematic view of a second main surface of a substrate according to yet another embodiment of the present application.

FIG. 19 is a structural schematic view of a second main surface of a substrate according to still yet another embodiment of the present application.

FIG. 20 is a structural schematic view of a display apparatus according to still yet another embodiment of the present application.

FIG. 21 is a structural schematic view of a display apparatus according to another embodiment of the present application.

### DETAILED DESCRIPTION

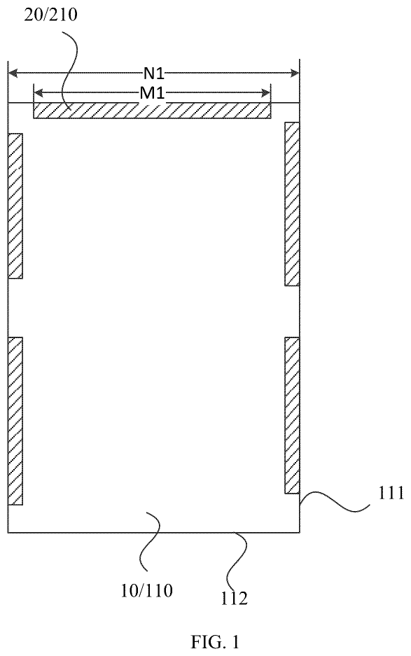

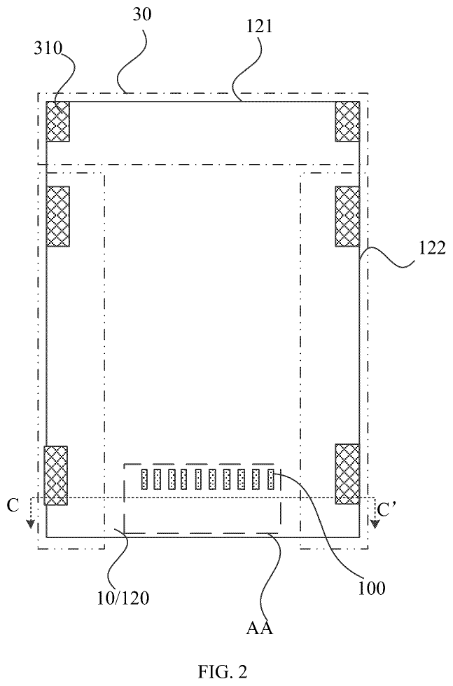

FIG. 1 is a structural schematic view of a first main surface of a substrate according to an embodiment of the present application, and FIG. 2 is a structural schematic view of a second main surface of a substrate according to an embodiment of the present application. Referring to FIG. 1 and FIG. 2, a display module includes a display panel, which includes a substrate 10, an electrostatic structure 20, and at least one conductive pad setting region 30. The substrate 10 includes a first main surface 110, and a second main surface 120 opposite to the first main surface 110. The electrostatic structure 20 is disposed on the first main surface 110. The at least one conductive pad setting region 30 is disposed on the second main surface 120 and includes at least one conductive pad 310 coupled to the electrostatic structure 20.

As shown in FIG. 1 and FIG. 2, the display module includes a display panel, which is not limited in embodiments in the present application. In other embodiments, the display module may further include a plurality of display panels. Specifically, the display panel includes a substrate 10 including a first main surface 110, and a second main surface 120 opposite to the first main surface. The first main surface 110 may be the light-out surface of the display panel, that is, the first main surface 110 includes a display area (not shown in the drawings). For example, when the display panel includes an OLED display panel or a Micro-LED display panel, the display area is provided with a plurality of light-emitting elements arranged in an array that emit light to display the images. When the display panel includes an LCD display panel, the display area includes a liquid crystal layer, and a color filter substrate located on the side of the liquid crystal layer facing away from the substrate. The light transmittance state of the liquid crystal layer is controlled by controlling the deflection state of the liquid crystal molecules in the liquid crystal layer, and the color display of the image is realized by the color resist block of the color filter substrate. When the display panel includes electronic paper, the display area includes an electrophoretic layer, and the image is displayed by reflecting light through the electrophoretic layer. The second main surface 120 may be the non-light-emitting surface of the display panel, and a signal transmission element may be disposed on the non-light-out surface. For example, the second main surface 120 may include a driving pad setting region AA, and the driving pad 100 in the driving pad setting region AA provides a data signal or a scanning signal for the data signal line or the scanning signal line of the first main surface 110.

In embodiments shown in FIG. 1, the first main surface 110 is further provided with an electrostatic structure 20. Specifically, the first main surface 110 includes a plurality of side edges, and the electrostatic structure 20 may be provided on one side edge of the first main surface 110, or may be provided on a plurality of side edges of the first main surface 110. In addition, the second main surface 120 is further provided with at least one conductive pad setting region 30. Specifically, when the electrostatic structure 20 is located on a side edge of the first main surface 110, the second main surface 120 includes a conductive pad setting region 30 corresponding to the electrostatic structure 20 of the first main surface 110, or may be staggered relative to the electrostatic structure 20 of the first main surface 110, which does not limit in the embodiments of the present application. When the electrostatic structure 20 is disposed on a plurality of side edges of the first main surface 110, the second main surface 120 may include a conductive pad setting region 30, or may include a plurality of conductive pad setting regions 30. When the second main surface 120 includes a conductive pad setting region 30 corresponding to the electrostatic structure 20 on any side edge of the first main surface 110. When the second main surface 120 includes a plurality of conductive pad setting regions 30, the plurality of conductive pad setting regions 30 correspond to the electrostatic structure 20 on the plurality of side edges of the first main surface 110. In this way, it is convenient for the conductive pad 310 of the conductive pad setting region 30 to couple to the electrostatic structure 20, and when static electricity is generated in the display panel, the electrostatic structure 20 disposed on the first main surface 110 can timely introduce the static electricity into the conductive pad 310 on the second main surface 120, and discharge the static electricity through the conductive pad 310, thereby avoiding the accumulation of static electricity on the wiring or driving device in the display panel to affect the performance of the display panel, improving the electrostatic protection performance of the display panel, and improving the reliability of the display panel.

It should be noted that the electrostatic structure 20 may be connected to the conductive pad 310 through side wirings located on the side surface of the display panel, and the vias can be directly punched in the display panel to achieve electrical connection between the electrostatic structure 20 and the conductive pad 310 through vias. The embodiments of the present application does not limit the specific electrical connection method between the electrostatic structure 20 and the conductive pad 310, which can be set by those skilled in the art as needed.

In summary, the substrate in embodiments of the present application includes a first main surface and a second main surface that are disposed opposite to each other. The electrostatic structure located on the first main surface is coupled to the conductive pad located on the second main surface, and when static electricity is generated in the display panel, the electrostatic structure located on the first main surface can timely introduce the static electricity into the conductive pad located on the second main surface, and discharge the static electricity through the conductive pad, thereby avoiding the accumulation of static electricity on the wiring or driving device in the display panel to affect the performance of the display panel, improving the electrostatic protection performance of the display panel, and improving the reliability of the display panel. In addition, the conductive pad is disposed on the second main surface, which can save the design space of the first main surface, thereby facilitating the reduction of the bezel area of the display panel.

Based on the above embodiments, the conductive pad 310 can be electrically connected to a fixed terminal (not shown in the drawings). Specifically, the fixed terminal can be a low-potential fixed terminal. The conductive pad 310 is electrically connected to the low-potential fixed terminal, that is, the conductive pad 310 transmits a low-potential signal, it is ensured that the conductive pad 310 can discharge the static electricity introduced by the electrostatic structure 20. It should be noted that the electrostatic discharge method of the conductive pad 310 is not limited in embodiments of the present application. In other embodiments, the conductive pad 310 can be a ground pad (not shown in drawings), and the static electricity introduced by the electrostatic structure 20 is discharged through the ground pad.

Based on the above embodiments, referring to FIG. 1, the electrostatic structure 20 includes a plurality of electrostatic structure subsections 210. The length of the electrostatic structure subsection 210 is M1 along the extending direction of the electrostatic structure subsection 210. The first main surface 110 includes a first side 111 and a second side 112, the length of the first side 111 is greater than that of the second side 112, and the length of the second side 112 is N1, where M1>N1/2. The plurality of the electrostatic structure subsections 210 are spaced apart.

The second side 112 is the shortest side among the plurality of sides of the first main surface 110, and the length of the second side 112 is N1. The length M1 of the electrostatic structure subsection 210 is greater than half of that of the second side 112 to enable the length M1 of the electrostatic structure subsection 210 to be long enough, so that the electrostatic structure subsection 210 has a stronger ability to attract static electricity, thereby enabling the static electricity generated in the display panel to be introduced into the conductive pad 310 in time. On this basis, the plurality of electrostatic structure subsections 210 are spaced apart, that is, the electrostatic structure 20 is a segmented structure. In an embodiment shown in FIG. 1, when M1>N1/2, the second side 112 includes an electrostatic structure subsection 210, and there are at least two ones of the plurality of electrostatic structure subsections 210 are disposed on the same first side 111. In other words, the first side 111 may include at least two electrostatic structure subsections 210, which is not limited in the embodiments in the present application. In other embodiments, the plurality of electrostatic structure subsections 210 can be disposed on different sides of the first main surface 110 (the different sides include, for example, two first sides 111 at different positions as shown in the drawings, and two second sides 112 at different positions), that is, the first side 111 and the second side 112 each include an electrostatic structure subsection 210, which can be set by those skilled in the art as needed.

It should be noted that the lengths of different electrostatic structure subsections 210 may be the same or different, which is not limited in embodiments of the present invention. It only requires that the length of at least one electrostatic structure subsection 210 is greater than half of that of the second side 112.

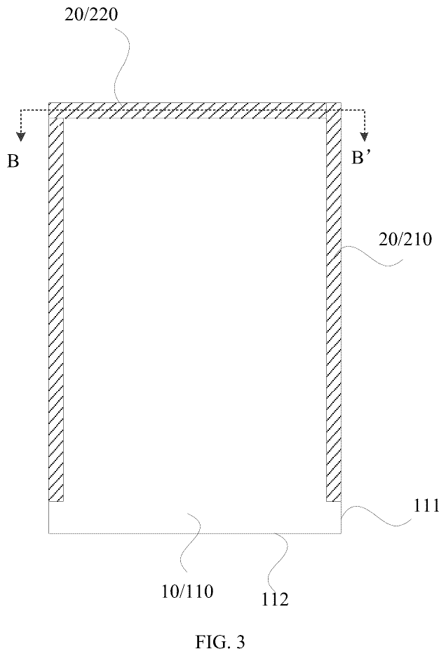

In another embodiment, FIG. 3 is a structural schematic view of a first main surface of a substrate according to another embodiment of the present application. As shown in FIG. 3, the first main surface 110 includes a first side 111 and a second side 112, and the extending direction of the first side 111 intersects the extending direction of the second side 112. The electrostatic structure 20 includes a first electrostatic structure subsection 210 and a second electrostatic structure subsection 220, and the extending direction of the first electrostatic structure subsection 210 is the same as that of the first side 111, and the extending direction of the second electrostatic structure subsection 220 is the same as that of the second side 112. The first electrostatic structure subsection 210 is electrically connected to the second electrostatic structure subsection 220.

In embodiments shown in FIG. 3, the first electrostatic structure subsection 210 is disposed along the extending direction of the first side 111, and the second electrostatic structure subsection 220 is disposed along the extending direction of the second side 112. When the two first sides 111 at different positions are each provided with the first electrostatic structure subsection 210, the length of the second electrostatic structure subsection 220 can be equal to that of the second side 112, so that the two ends of the second electrostatic structure subsection 220 are respectively electrically connected to an end of each of the two first electrostatic structure subsections 210 to form a ring structure. In this way, the electrostatic structure 20 with the ring structure is continuously disposed on different sides, which can further increase the electrostatic attraction ability of the electrostatic structure 20 to static electricity, can enable the electrostatic structure 20 to timely introduce static electricity into the conductive pad 310 for electrostatic discharge, and can improve the electrostatic protection performance of the display module.

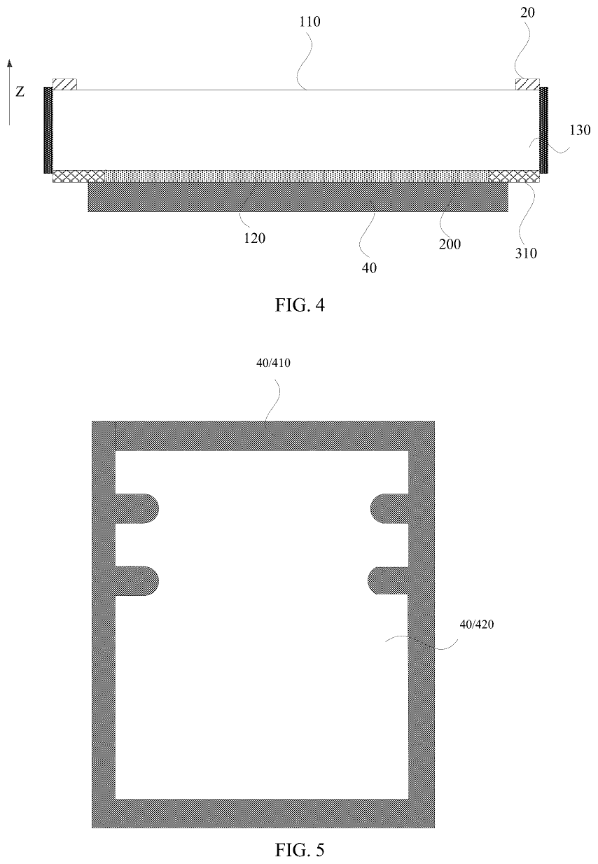

FIG. 4 is a cross-sectional schematic view of FIG. 3 along a line B-B′. Referring to FIG. 3 and FIG. 4, the display module further includes at least one conductive bracket structure 40. In the thickness direction Z of the display panel, the display panel at least partially overlaps the at least one conductive bracket structure 40. The conductive bracket structure 40 is fixed on the second main surface 120 and electrically connected to the conductive pad 310.

In embodiments shown in FIG. 3 and FIG. 4, the display module includes a display panel and a conductive bracket structure 40 corresponding to the display panel and used to support the display panel. The conductive bracket structure 40 is disposed on the second main surface 120 and at least partially overlaps the conductive pad 310 in the thickness direction Z of the display panel, so that the conductive bracket structure 40 is electrically connected to the conductive pad 310. In this way, when static electricity is generated in the display panel, the electrostatic structure 20 located on the first main surface 110 absorbs the static electricity in time and introduces it into the conductive pad 310 located on the second main surface 120, and then the conductive pad 310 transmits the static electricity to the conductive bracket structure 40 for the electrostatic discharge. The volume of the conductive bracket structure 40 is larger than the volume of the conductive pad 310 (corresponding to the display panel). The larger conductive bracket structure 40 has a larger surface area, and when static electricity is discharged through the conductive bracket structure 40, more conduction paths can be provided for static electricity, thereby accelerating the electrostatic discharge speed, and improving the static electricity protection effect of the display module.

It should be noted that the conductive bracket structure 40 may be fixedly electrically connected to the conductive pad 310 by means of conductive silver paste, conductive glue, conductive cloth, or the like, which is not limited thereto in embodiments of the present application, and can be set by those skilled in the art can as needed. In addition, an adhesive layer 200 can further be disposed between the conductive bracket structure 40 and the second main surface 120, that is, the conductive bracket structure 40 is fixed on the second main surface 120 through the adhesive layer 200 to ensure the fixed connection between the conductive bracket structure 40 and the second main surface 120. Furthermore, when the conductive bracket structure 40 is a whole layer structure, that is, when the conductive bracket structure 40 overlaps the driving pad setting region AA of the second main surface 120 in the thickness direction Z of the display panel, the adhesive layer 200 can further act as an insulating layer, thereby avoiding the conductive bracket structure 40 from having a greater impact on the driving pad setting region AA when the electrostatic discharge occurs to ensure the normal operation of the display module.

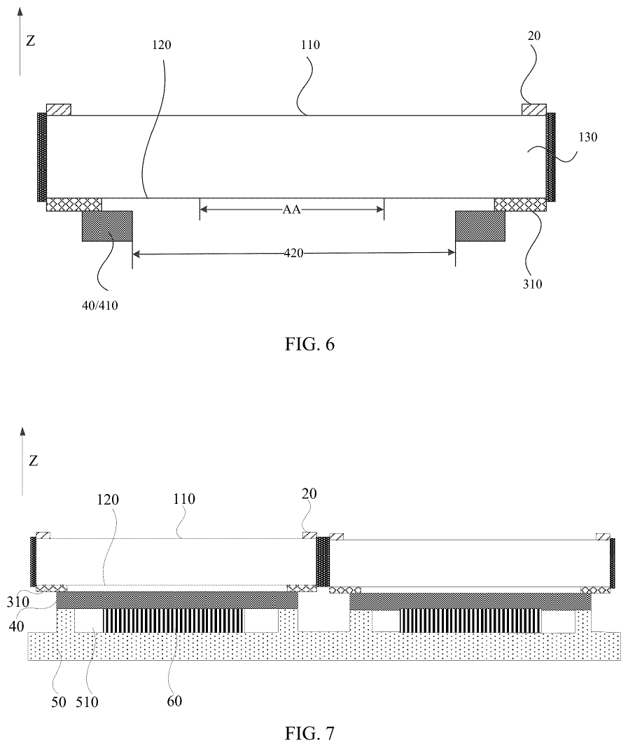

FIG. 5 is a structural schematic view of a conductive bracket structure according to an embodiment of the present application, and FIG. 6 is a cross-sectional schematic view of FIG. 2 along a line C-C′. Referring to FIG. 2, FIG. 5 and FIG. 6, the second main surface 120 further includes a driving pad setting region AA including a plurality of driving pads 100. The conductive bracket structure 40 includes a conductive bracket body 410 and a hollow area 420. The hollow area 420 at least partially overlaps the driving pad setting region AA in the thickness direction Z of the display panel, and the conductive bracket body 410 at least partially overlaps the conductive pad 310.

In embodiments shown in FIG. 2, FIG. 5 and FIG. 6, the second main surface 120 further includes a driving pad setting region AA, and the driving pad setting region AA and the conductive pad setting region 30 are staggered in the thickness direction Z of the display panel, that is, the driving pad setting region AA and the conductive pad setting region 30 are not in the same area. The driving pad setting region AA includes a plurality of driving pads 100 electrically connected to the data signal lines and the scanning signal lines of the first main surface 110 to provide data signals for the data signal lines and provide scanning signals for the scanning signal lines through the driving pads 100. In an embodiment of the present application, the conductive pads 310 are electrically connected to the conductive bracket structure 40 for electrostatic discharge. The normal operation of the signal of the driving pad 100 will be affected during the electrostatic discharge process, so that a conductive bracket structure 40 includes a conductive bracket body 410 and a hollow area 420. The hollow area 420 at least partially overlaps the driving pad setting region AA in the thickness direction Z of the display panel, so that the electrostatic discharge is not performed at the position corresponding to the driving pad setting region AA in the conductive bracket structure 40, ensuring that the signal transmission process of the driving pad 100 is not affected by the electrostatic discharge. In addition, the conductive bracket body 410 at least partially overlaps the conductive pad 310 in the thickness direction Z of the display panel, so that the electrical connection method between the conductive bracket body 410 and the conductive pad 310 is simple, ensuring that the conductive pad 310 can transmit static electricity to the conductive bracket body 410.

It should be noted that, in embodiments shown in FIG. 5, the conductive bracket body 410 includes a plurality of protrusion structures (not shown in drawings) at least partially overlapping the conductive pad 310 to simplify the electrical connection between the conductive bracket body 410 and the conductive pad 310.

The above embodiments are described by taking the display module including one display panel and one conductive bracket structure 40 as an example, which is not limited thereto. In other embodiments, the display module may further include a plurality of display panels and a plurality of conductive bracket structures 40.

FIG. 7 is a cross-sectional schematic view of a display module according to an embodiment of the present application. Referring to FIG. 7, a plurality of conductive bracket structures 40 are independently spaced apart. The display module includes a plurality of display panels and a plurality of conductive bracket structures 40. The plurality of display panels are spliced together to form a spliced display panel, and the plurality of conductive bracket structures 40 are used to support a plurality of display panels in the spliced display panel to enable the display panels to correspond to the conductive bracket structures 40, that is, each display panel may be supported by a conductive bracket structure 40, or each display panel may be supported by a plurality of conductive bracket structures 40. At the same time, each conductive bracket structure 40 is electrically connected to the conductive pad 310 of the corresponding display panel, so that each display panel can perform the electrostatic discharge through the corresponding conductive bracket structure 40. On this basis, a plurality of conductive bracket structures 40 can be independently spaced apart, that is, a gap is provided between two adjacent conductive bracket structures 40, and the display panel performs the electrostatic discharge through the corresponding one or more conductive bracket structures 40. In other embodiments, the plurality of the conductive bracket structures 40 can also be formed integrally, that is, the plurality of the conductive bracket structures 40 are electrically connected to each other to form an integral structure. In this way, the integral structure has a larger volume to provide more electrostatic discharge paths, thereby accelerating the electrostatic discharge speed, and improving the electrostatic protection effect of the display module.

Based on the above embodiment, referring to FIG. 7, the display module includes a plurality of display panels and a conductive splicing frame 50 disposed on a side of the conductive bracket structure 40 facing away from the display panel, and the conductive bracket structure 40 is fixed to the display panel and the conductive splicing frame 50. A plurality of accommodating spaces 510 are formed between the conductive splicing frame 50 and the conductive bracket structures 40. The display module further includes a plurality of printed circuit boards 60 disposed in the accommodating space 510 and electrically connected to the conductive splicing frame 50 and the conductive bracket structures 40.

In embodiments shown in FIG. 2 and FIG. 7, a plurality of display panels are spliced together to form a spliced display panel. The conductive bracket structures 40 are used to support each display panel, and the conductive splicing frame 50 is used to support the spliced display panel as a whole. The side of the conductive bracket structure 40 facing away from the display panel is fixed to the conductive splicing frame 50 provided with a groove at a position corresponding to the conductive bracket structure 40, so that the conductive splicing frame 50 and the conductive bracket structure 40 are fixed to form a receiving space 510. A printed circuit board 60 is disposed in the receiving space 510 and can be electrically connected to the driving pad 100 through the hollow area 420 of the conductive bracket structure 40 to provide data signals, scanning signals, or the like to the driving pad 100. In addition, the printed circuit board 60 is further electrically connected to the conductive splicing frame 50 and the conductive bracket structures 40, that is, the conductive bracket structures 40, the printed circuit board 60, and the conductive splicing frame 50 are commonly grounded to form a full-link conduction of the display panel, the conductive bracket structures 40 and the conductive splicing frame 50. In this way, the static electricity generated in the display panel can be discharged through the electrostatic structure 20, the conductive pad 310, the conductive bracket structure 40, and the conductive splicing frame 50, so as to avoid the accumulation of static electricity inside the display panel and cause damage. The static electricity generated on the back of the display panel can be directly discharged through the conductive bracket structure 40 and the conductive splicing frame 50, so as to avoid the accumulation of static electricity on the back of the display panel and damage to the display panel, thereby further improving the electrostatic protection performance of the display module.

It should be noted that, as shown in FIG. 7, when the plurality of the display panels are spliced together, two adjacent display panels can be spliced together through side wiring located on the side surface of the display panel, and the spliced display panels are supported as a whole by the conductive splicing frame 50. It is understandable that in FIG. 7, the two adjacent display panels electrically connected through side wirings are spliced with each other, which is not limited. In other embodiments, an insulating layer can be provided between the side wirings of two adjacent display panels, and the splicing can be performed by means of an insulating layer, which can be set by those skilled in the art as needed.

Based on the above embodiment, FIG. 8 is a cross-sectional schematic view of a display module according to another embodiment of the present application. Referring to FIG. 8, the printed circuit boards 60 includes a first printed circuit board 610 disposed on a side of the accommodation space 510 close to the conductive bracket structure 40, and a second printed circuit board 620 disposed on a side of the accommodation space 510 close to the conductive splicing frame 50. The first printed circuit board 610 is fixed and electrically connected to the conductive bracket structure 40, the second printed circuit board 620 is fixed and electrically connected to the conductive splicing frame 50, and the first printed circuit board 610 is electrically connected to the second printed circuit board 620.

As shown in FIG. 8, the printed circuit boards 60 may include one or a plurality of the first printed circuit boards 610 and a plurality of the second printed circuit boards 620. The first printed circuit board 610 is disposed on the surface of the conductive splicing frame 50 close to a side of the conductive bracket structure 40 and used to provide a driving signal. The second printed circuit board 620 is disposed on the surface of the conductive bracket structure 40 close to a side of the conductive splicing frame 50 and used to transmit a driving signal. The plurality of second printed circuit boards 620 corresponds to the plurality of display panels, that is, the second printed circuit boards 620 are electrically connected to the driving pad 100 in the corresponding display panel through the hollow area 410, and the first printed circuit board 610 can be communicatively connected to the plurality of the second printed circuit boards 620 through a floating connector. Furthermore, the first printed circuit board 610 can provide the same driving signal to the plurality of the second printed circuit boards 620 for transmitting the same driving signal to the corresponding display panels to enable the plurality of the display panels to display the same images; or the first printed circuit board 610 can provide different driving signals to the plurality of the second printed circuit boards 620 for transmitting different driving signals to the corresponding display panels to enable the plurality of display panels to display different images. Therefore, the images display of the spliced display panel is realized by the first printed circuit board 610 and the second printed circuit boards 620. In addition, the first printed circuit board 610 is fixed and electrically connected to the conductive bracket structure 40, the second printed circuit board 620 is fixed and electrically connected to the conductive splicing frame 50, and the first printed circuit board 610 is electrically connected to the second printed circuit board 620. That is, the conductive bracket structure 40, the first printed circuit board 610, the second printed circuit board 620, and the conductive splicing frame 50 are commonly grounded, so that the static electricity generated on the back of the display panel can be directly discharged through the conductive bracket structure 40 and the conductive splicing frame 50, avoiding the accumulation of static electricity on the back of the display panel and damaging the display panel, further improving the electrostatic protection performance of the display module.

It should be noted that in embodiments of the present application, the first printed circuit board 610 and the conductive bracket structure 40 are fixed by screws, and a copper leak is disposed at the connection position of the first printed circuit board 610 and the conductive bracket structure 40 for grounding to ensure that the first printed circuit board 610 is commonly grounded with the conductive bracket structure 40. The same method can be used to achieve that the second printed circuit board 620 is commonly grounded with the conductive splicing frame 50, which is not limited thereto. In other embodiments, other methods can be used as long as the first printed circuit board 610 is commonly grounded with the conductive bracket structure 40, and the second printed circuit board 620 is commonly grounded with the conductive splicing frame 50.

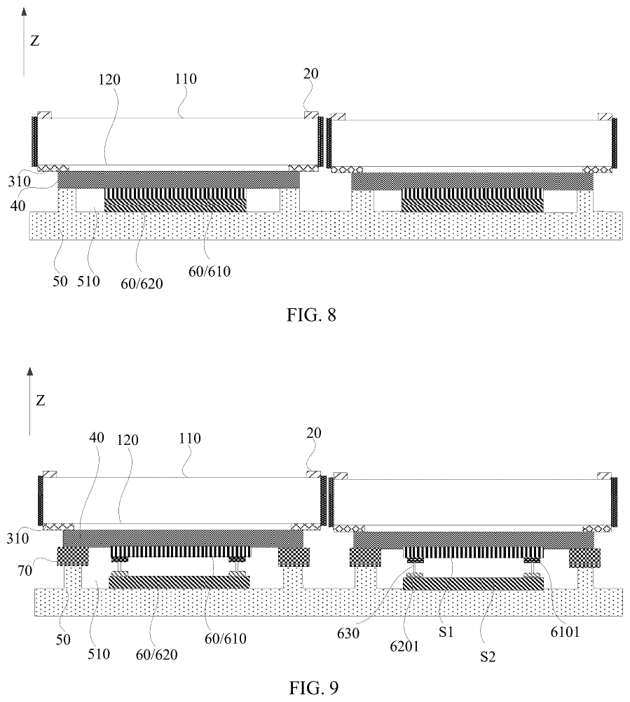

FIG. 9 is a cross-sectional schematic view of a display module according to yet another embodiment of the present application. Referring to FIG. 9, the first printed circuit board 610 includes a first surface S1 facing away from the conductive bracket structure 40, which is provided with a plurality of first pads 6101. The second printed circuit board 620 includes a second surface S2 facing away from the conductive splicing frame 50, which is provided with a plurality of second pads 6201. The display module further includes a plurality of retractable probes 630, and the first pads 6101 are electrically connected to the second pads 6201 through the retractable probes 630.

In embodiments shown in FIG. 9, the first surface S1 of the first printed circuit board 610 is disposed opposite to the second surface S2 of the second printed circuit board 620. A plurality of first pads 6101 are formed at a preset position on the first surface S1, and a plurality of second pads 6201 are disposed at a corresponding position on the second surface S2, that is, in the thickness direction Z of the display panel, the first pads 6101 at least partially overlaps the second pads 6201, thereby simplifying the electrical connection between the first pads 6101 and the second pads 6201. Furthermore, on the basis of the first printed circuit board 610 being commonly grounded with the conductive bracket structure 40, and the second printed circuit board 620 being commonly grounded with the conductive splicing frame 50, the first printed circuit board 610 is commonly grounded with the second printed circuit board 620, thereby improving the electrostatic protection capability of the display module. In addition, as shown in FIG. 9 the first pads 6101 are electrically connected to the second pads 6201 through retractable probes 630. After the conductive splicing frame 50 is assembled, the first printed circuit board 610 and the second printed circuit board 620 in the accommodating space 510 may be at different heights. In other words, there is a gap between the bonding surface of the first printed circuit board 610 and the conductive bracket structure 40, and there is a gap between the bonding surface of the second printed circuit board 620 and the conductive splicing frame 50. The existence of the gap easily causes the first printed circuit board 610 or the second printed circuit board 620 to fall off. Therefore, the first pad 6101 is electrically connected to the second pad 6201 through the retractable probes 630 for providing elastic support force and playing a role similar to a spring. When there is a gap between the bonding surface of the first printed circuit board 610 and the conductive bracket structure 40, or there is a gap between the bonding surface of the second printed circuit board 620 and the conductive splicing frame 50, the retractable probe 630 can provide a larger support force at the position where the gap exists (the lower position), thereby raising the lower position to reduce or even eliminating the gap, and ensuring the horizontal arrangement of the first printed circuit board 610 and the second printed circuit board 620.

Based on the above embodiment, referring to FIG. 9, the display module further includes a plurality of magnet structures 70, and the conductive bracket structure 40 is detachably fixedly connected to the conductive splicing frame 50 though the magnet structure 70.

The conductive bracket structure 40 is detachably fixedly connected to the conductive splicing frame 50. In embodiments shown in FIG. 9, the conductive bracket structure 40 is detachably fixedly connected to the conductive splicing frame 50 though a magnet structure 70. The magnet structure 70 is detachable in a simple manner. When there is a problem with the display panel or the printed circuit board 60, it is convenient to repair or replace the printed circuit board 60 in the accommodation space 610.

It should be noted that embodiments of the present application is only exemplary to achieve detachable fixed connection by means of the magnet structures 70, which is not limited thereto. In other embodiments, it can further be achieved by other means and can be set by those skilled in the art as needed.

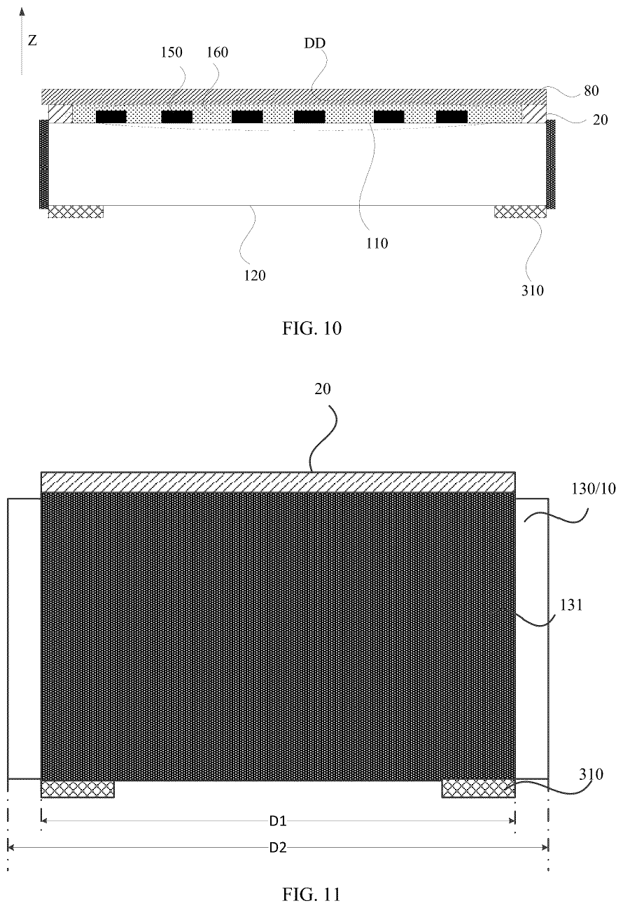

FIG. 10 is a cross-sectional schematic view of a display module according to still yet another embodiment of the present application. Referring to FIG. 10, the display module further includes a light-transmitting conductive layer 80 disposed on the first main surface 110 and coupled to the conductive pad 310.

The first major surface 110 further includes a display area DD, and the light-transmitting conductive layer 80 is disposed on a side of the display area DD facing away from the substrate 10. For example, when the display panel includes an OLED display panel or a Micro-LED display panel, the display area DD includes a light-emitting element 150 and an encapsulation layer 160 covering the light-emitting element 150, and the light-transmitting conductive layer 80 is disposed on a side of the encapsulation layer facing away from the substrate 10; when the display panel includes an LCD display panel, the light-transmitting conductive layer 80 is disposed on a side of the liquid crystal layer facing away from the substrate 10; when the display panel includes an electronic paper, the light-transmitting conductive layer 80 is disposed on a side of the electrophoretic layer facing away from the substrate 10. When static electricity exists on the front of the display panel, for example, static electricity being generated on the front of the display panel due to a finger touching the outermost cover plate of the display panel, or clothing rubbing against the outermost cover plate of the display panel, the static electricity will enter the display area DD (such as the light-emitting element) and the driving circuit under the display area DD, thereby affecting the normal operation of the display area and the driving circuit. Furthermore, the light-transmitting conductive layer 80 is disposed on the side of the display area DD facing away from the substrate 10, the static electricity on the front of the display panel is attracted by the light-transmitting conductive layer 80, and the static electricity is discharged though the conductive pad 310 coupled to the light-transmitting conductive layer 80, thereby preventing the static electricity on the front of the display panel from affecting the normal operation of the display area and the driving circuit. In embodiments shown in FIG. 10, the light-transmitting conductive layer 80 is electrically connected to the electrostatic structure 20 through a conductive glue or a conductive silver paste, and the electrostatic structure 20 is electrically connected to the conductive pad 310 through side wirings, so that the light-transmitting conductive layer 80 is electrically connected to the conductive pad 310. In this way, when static electricity exists on the front of the display panel, the light-transmitting conductive layer 80 disposed above the display area DD can promptly introduce the static electricity into the conductive pad 310 of the second main surface 120, and discharge the static electricity through the conductive pad 310, thereby avoiding the accumulation of static electricity on the front of the display panel to affect the performance of the display panel, improving the static electricity protection performance of the front of the display panel, and improving the reliability of the display module.

It should be noted that since the light-transmitting conductive layer 80 is disposed above the display area DD and at least partially overlaps the display area, and the display area DD is the light-out side of the display panel, so that the material of the light-transmitting conductive layer 80 is required to include a light-transmitting material to prevent the light-transmitting conductive layer 80 from affecting the light output amount of the display area.

Based on the above embodiments, FIG. 11 is a structural schematic view of a side surface of a substrate according to an embodiment of the present application. Referring to FIG. 11, the substrate 10 further includes a plurality of side surfaces 130 connecting the first main surface 110 and the second main surface 120. The side surface 130 is provided with at least one side wiring 131 electrically connected to the electrostatic structure 20 and the conductive pad 310.

As shown in FIG. 1, FIG. 2, and FIG. 11, the substrate 10 may include four side surfaces 130, each of which is connected to a side of each of the first main surface 110 and a side of the second main surface 120. The plurality of side surfaces 130 are connected to each other, and a rectangular parallelepiped structure is formed by the first main surface 110, the second main surface 120, and the plurality of side surfaces 130. In addition, The electrostatic structure 20 is coupled to the conductive pad 310 through the side wirings 131 disposed on the side surfaces 130, that is, the side wirings 131 are electrically connected to the corresponding electrostatic structure 20 and the corresponding conductive pad 310, respectively, so as to realize that the electrostatic structure 20 is commonly grounded with the conductive pad 310. On the basis of improving the electrostatic protection performance of the display panel, the electrical connection method between the electrostatic structure 20 and the conductive pad 310 is ensured to be simple. It can be understood that the electrostatic structure 20 disposed adjacent to the side wiring 131 is the electrostatic structure 20 corresponding to the side wiring 131, and the conductive pad 310 disposed adjacent to the side wiring 131 is the conductive pad 310 corresponding to the side wiring 131.

It should be noted that when the side wiring 131 is electrically connected to the electrostatic structure 20, the side wiring 131 may extend beyond the first main surface 110, so that there is an overlapping portion between the side wiring 131 and the electrostatic structure 20, thereby ensuring the stability of the electrical connection between the side wiring 131 and the electrostatic structure 20. Similarly, when the side wiring 131 is electrically connected to the conductive pad 310, the side wiring 131 may extend beyond the second main surface 120, so that there is an overlapping portion between the side wiring 131 and the conductive pad 310, thereby ensuring the stability of the electrical connection between the side wiring 131 and the conductive pad 310.

Based on the above embodiments, still referring to FIG. 11, a side wiring 131 is provided on the side surface 130. The line width of the side wiring 131 is D1, and the width of the long side of the side surface 130 is D2, where D1>D2/2.

In embodiments shown in FIG. 11, the long side of the side surface 130 can be understood as the side connecting the side surface 130 and the first main surface 110 or the second main surface 120. The line width of the side wiring 131 can be understood as the width of the side wiring 131 in the extending direction of the long side of the side surface 130. The line width D1 of the side wiring 131 is set to be greater than half of the width D2 of the long side of the side surface 130, that is, one side wiring 131 is disposed on the same side surface 130, so that the side wiring 131 has a larger surface area, providing more conduction paths for static electricity, thereby accelerating the electrostatic conduction speed of the side wirings 131, and ensuring that the static electricity can be discharged though the conductive pad 310 in time.

It should be noted that in other embodiments, the line width D1 of the side wiring 131 may be equal to the width D2 of the long side of the side surface 130. In other words, the side wirings 131 are disposed on the entire side surface 130, which can further accelerate the electrostatic conduction speed of the side wirings 131.

It should also be noted that, in embodiments shown in FIG. 11, the length of the electrostatic structure 20 is the same as the line width of the side wiring 131 in the extending direction of the long side of the side surface 130, which is not limited in embodiments of the present application. In other embodiments, the length of the electrostatic structure 20 may be smaller than the line width of the side wiring 131, or the length of the electrostatic structure 20 may be greater than the line width of the side wiring 131, which can be set by those skilled in the art as needed.

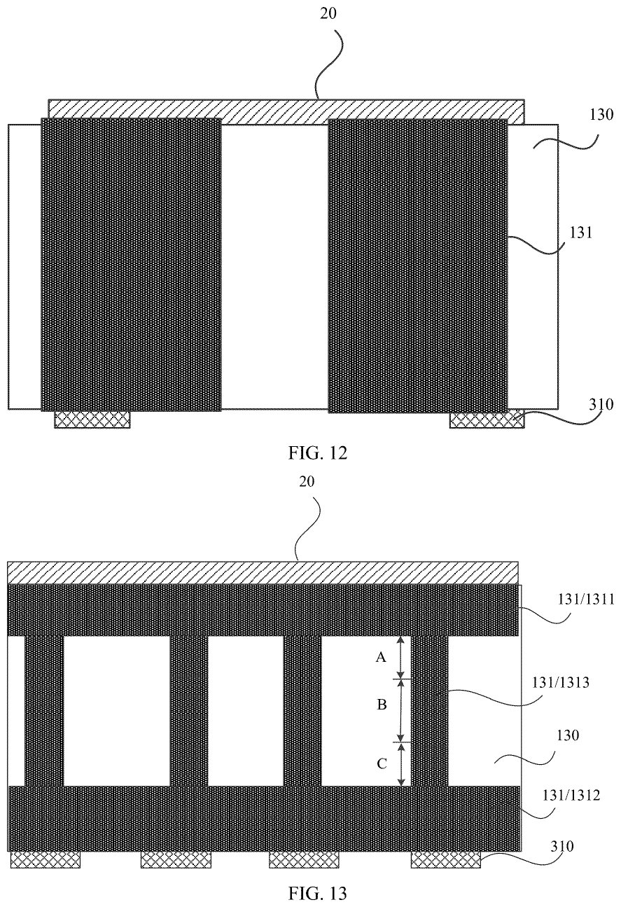

Based on the above-mentioned embodiments, FIG. 12 is a structural schematic view of a plurality of side surfaces of a substrate according to another embodiment of the present application. Referring to FIG. 12, at least two side wirings 131 are disposed on the side surface 130, and a plurality of side wirings 131 are spaced apart. When preparing the side wirings 131 on the side surface 130, a specific process is required, and if the line width of the side wiring 131 is too greater (i.e., the area is too large), it will result in a long preparation time and a greater difficulty in preparation. Therefore, based on the consideration of preparation efficiency and conductivity and compared with the side wirings 131 disposed on the entire surface of the side surface 130, a plurality of side wirings 131 spaced apart are prepared on the side surface 130, the line width of the side wirings 131 can be reduced, and the preparation process is simple while improving the electrostatic protection effect of the display module.

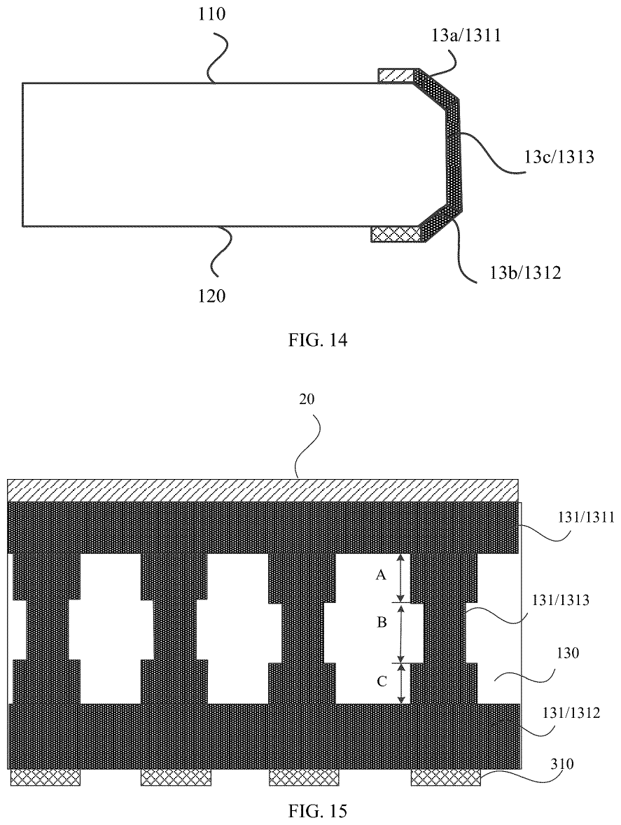

It should be noted that, in embodiments shown in FIG. 12, the plurality of side wirings 131 are spaced apart, so that when the plurality of side wirings 131 are electrically connected to the same electrostatic structure 20, the length of the electrostatic structure 20 is greater than the length of each side wire 131 in the extending direction of the long side of the side surface 130. FIG. 13 is a structural schematic view of a side surface of a substrate according to yet another embodiment of the present application, and FIG. 14 is a cross-sectional schematic view of a side surface of a substrate according to yet another embodiment of the present application. Referring to FIG. 13 and FIG. 14, the side surface 130 includes a first chamfered subsection 13a, a second chamfered subsection 13b, and a planar portion 13c. The first chamfered subsection 13a is connected to the first main surface 110 and the planar portion 13c, the planar portion 13c is connected to the first chamfered subsection 13a and the second chamfered subsection 13b, and the second chamfered subsection 13b is connected to the planar portion 13a and the second main surface 120. The side wiring 131 includes a first side wiring subsection 1311, a second side wiring subsection 1312, and a plurality of third side wiring subsections 1313. The first side wiring subsection 1311 is disposed at the first chamfered subsection 13a, the second side wiring subsection 1312 is disposed at the second chamfered subsection 13b, and the third side wiring subsection 1313 is disposed at the plane portion 13c.

The first side wiring subsection 1311 is electrically connected to the electrostatic structure 20, the second side wiring subsection 1312 is electrically connected to the conductive pad 310, and the third side wiring subsection 1313 is electrically connected to the first side wiring subsection 1311 and the second side wiring subsection 1312.

In embodiments shown in FIG. 13 and FIG. 14, the side surface 130 includes a first chamfered subsection 13a, a second chamfered subsection 13b, and a plane portion 13c. The first chamfered subsection 13a and the second chamfered subsection 13b may be chamfered with an inclined surface, that is, the first chamfered subsection 13a and the second chamfered subsection 13b each includes an inclined plane; the first chamfered subsection 13a and the second chamfered subsection 13b may be chamfered with an arc surface, that is, the first chamfered subsection 13a and the second chamfered subsection 13b each includes an arc surface. The first chamfered subsection 13a is the connection position between the first side wiring subsection 1311 and the electrostatic structure 20, and the angle between the first chamfered subsection 13a and the first main surface 110 is greater than 90°. Thus, the difficulty of preparing and connecting the first side wiring portion 1311 and the electrostatic structure 20 can be reduced by the first chamfered subsection 13a. Similarly, the difficulty of preparing and connecting the second side wiring subsection 1312 and the conductive pad 310 can be reduced by the second chamfered subsection 13b. In addition, the first chamfered subsection 13a and the second chamfered subsection 13b each has a larger surface area than the original vertical plane due to the first chamfered subsection 13a and the second chamfered subsection 13b each including an inclined plane or an arc surface. In this way, when the first side wiring subsection 1311 is prepared on the first chamfered subsection 13a, and the second side wiring subsection 1312 is prepared on the second chamfered subsection 13b, the surface area of the first side wiring subsection 1311 and the second side wiring subsection 1312 can be increased, providing more conduction paths for static electricity, thereby accelerating the electrostatic conductive speed of the side wiring 131, and ensuring that the static electricity can be charged though the conductive pad 310 in time. In addition, the plane portion 13c is provided with a plurality of third side wiring subsections 1313 electrically connected to the first side wiring subsection 1311 and the second side wiring subsection 1312. As shown in FIG. 13, the extending direction of the first side wiring subsection 1311 is the same as that of the second side wiring subsection 1312, and the extending direction of the third side wiring subsection 1313 intersects that of the first side wiring subsection 1311. When the third side wiring subsections 1313 are electrically connected to the first side wiring subsection 1311 and the second side wiring subsection 1312, respectively, a gap is provided between adjacent third side wiring subsections 1313 which can reserve design space for other structures, thereby improving the space utilization of the display module.

On the basis of the above embodiments, referring to FIG. 13, the third side wiring subsections 1313 includes a first subsection A, a second subsection B, and a third subsection C. The first subsection A is disposed in a region of the third side wiring subsection 1313 close to the first side wiring subsection 1311, the third subsection C is disposed in a region of the third side wiring subsection 1313 close to the second side wiring subsection 1312, and the second subsection B connects the first subsection A and the third subsection C. The line widths of any two of the first subsection A, the second subsection B, and the third subsection C are the same.

In the embodiment shown in FIG. 13, the thickness of the third side wiring subsection 1313 is uniform in the extending direction of the third side wiring subsection 1313, that is, the line widths of any two of the first subsection A, the second subsection B and the third subsection C are the same, thereby ensuring that the preparation method of the third side wiring subsection 1313 is simple. In other embodiments, FIG. 15 is a structural schematic view of a side surface of a substrate according to still yet another embodiment of the present application. Referring to FIG. 15, the line widths of the first subsection A and the third subsection C are greater than that of the second subsection B. In the embodiment shown in FIG. 15, the first subsection A, the second subsection B, and the third subsection C form a structure having a wide top and bottom and an narrow middle. In other words, the line width of each of the first subsection A and the third subsection C are greater than that of the second part B by increasing the line widths of the first subsection A and the third subsection C. In this way, the line width of each of the first portion A and the third subsection C is increased, the impedance of the third side wire portion 1313 is reduced, the conductive connectivity of the third side wire portion 1313 is improved, the electrostatic conductive speed is accelerated, and the electrostatic protection effect of the display module is improved. In addition, in another embodiment, in the same third side wiring subsection 1313, the width of the third side wiring subsection 1313 is gradually decreased in the direction from the end of the third side wiring subsection 1313 close to the first side wiring subsection 1311 to the center region of the third side wiring subsection 1313, or in the direction from the end of the third side wiring subsection 1313 close to the second side wiring subsection 1312 to the center region of the third side wiring subsection 1313, that is, the upper and lower widths of the third side wiring subsection 1313 are gradually increased, thereby reducing the impedance of the third side wiring subsection 1313, and improving the conductivity of the third side wiring subsection 1313.

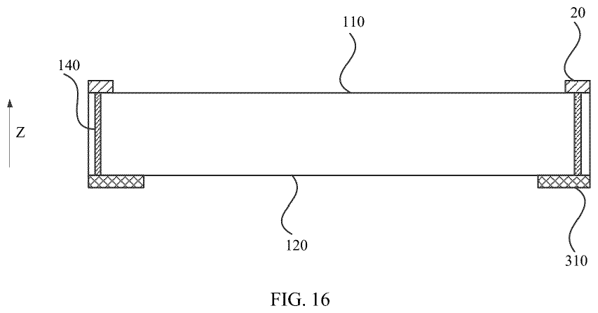

The above embodiments are all described in a manner that the electrostatic structure 20 is electrically connected to the conductive pad 310 through the side wirings 131, which is not limited to thereto. In other embodiments, FIG. 16 is a cross-sectional schematic view of a display module according to even still yet another embodiment of the present application. Referring to FIG. 16, the substrate 10 is provided with a via 140, and the electrostatic structure 20 is electrically connected to the conductive pad 310 through the via 140. In the embodiment shown in FIG. 16, the via 140 passes through the substrate 10, so that the electrostatic structure 20 located on the first main surface 110 is electrically connected to the conductive pad 310 located on the second main surface 120, thereby ensuring that the electrostatic structure 20 is common grounded with the conductive pad 310, thereby improving the electrostatic protection performance of the display panel.

It should be noted that FIG. 16 only exemplarily shows that the electrostatic structure 20 is electrically connected to the conductive pad 310 through one via 140, which is not limited in the present application. In other embodiments, the electrostatic structure 20 may further be electrically connected to the conductive pad 310 through a plurality of vias 140. It is understandable that the plurality of vias 140 are staggered in the thickness direction Z of the display panel.

Based on the above embodiments, referring to FIG. 2, and FIG. 4, the substrate 10 further includes a plurality of side surfaces 130 connecting the first main surface 110 and the second main surface 120. The second main surface 120 includes a plurality of conductive pad setting regions 30 located in the edge area of the second main surface 120 close to the side surfaces 130 and located on different sides of the second main surface 120.

In the embodiment shown in FIG. 2, the second main surface 120 includes three conductive pad setting regions 30 and a driving pad setting region AA. The driving pad setting region AA is staggered the conductive pad setting region 30 in the thickness direction Z of the display panel. The plurality of the driving pads 100 in the driving pad setting region AA are configured to provide driving signals for the data signal lines or scanning signal lines of the first main surface 110, the side surface 130 corresponding to a side edge of the second main surface 120 close to the driving pad setting region AA is required to be provided with a connecting wiring connecting the driving pad 100 and the data signal line or the scanning signal line, that is, the four sides of the second main surface 120 include three conductive pad setting regions 30 located on different sides of the second main surface 120 (except the side edge corresponding to the driving pad setting region AA). In this way, the conductive pad setting regions 30 are disposed on the plurality of the sides the first main surface 110 corresponding to the electrostatic structure 20 for electrostatic discharge, which increases the electrostatic discharge paths, thereby improving the electrostatic protection effect of the display panel.

It should be noted that the conductive pad setting region 30 is located in the edge area of the second main surface 120 close to the side surface 130, and the extending direction of the conductive pad setting region 30 is the same as that of the corresponding side of the second main surface 120. In this way, when the side wirings 131 are used to connect the conductive pad 310 and the electrostatic structure 20, the connection method of the side wiring 131 is ensured to be simple.

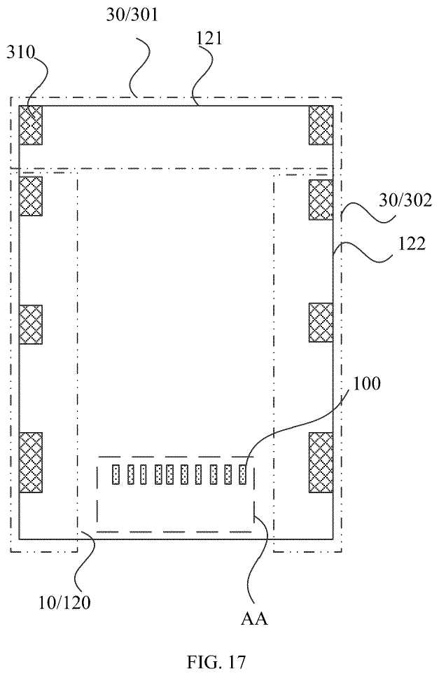

Based on the above embodiments, FIG. 17 is a structural schematic view of a second main surface of a substrate according to another embodiment of the present application. Referring to FIG. 17, the conductive pad setting region 30 includes a plurality of conductive pads 310. The second main surface 120 includes a third side 121 and a fourth side 122, and the length of the fourth side 122 is greater than the length of the third side 121. The plurality of conductive pad setting regions 30 include a first conductive pad setting region 301 disposed on the second main surface 120 close to the third side 121, and a second conductive pad setting region 302 disposed on the second main surface 120 close to the fourth side 122. The number of conductive pads 310 in the second conductive pad setting region 302 is greater than the number of conductive pads 310 in the first conductive pad setting region 301.

The length of the fourth side 122 is greater than that of the third side 121, and the range of the first main surface 110 corresponding to the fourth side 122 is greater than that of the first main surface 110 corresponding to the third side 121. In other words, the probability of static electricity occurring at the position of the first main surface 110 corresponding to the fourth side 122 is greater than the probability of static electricity occurring at the position of the first main surface 110 corresponding to the third side 121. Furthermore, a larger number of conductive pads 310 is disposed in the second conductive pad setting region 302, and the static electricity lead-out paths of the fourth side 122 is increased, thereby improving the static electricity protection effect of the display panel.

It should be noted that, in other embodiments, the arrangement density of the conductive pads 310 in the second conductive pad setting region 302 may be greater than that of the conductive pads 310 in the first pad setting region 301. Similarly, the electrostatic discharge paths of the fourth side 122 may be increased to improve the electrostatic protection effect of the display panel.

It should also be noted that when the conductive pad setting region 30 includes a plurality of the conductive pads 310 evenly spaced in the extending direction of the conductive pad setting region 30, that is, the distances between adjacent conductive pads 310 in the same conductive pad setting region 30 are the same to ensure that when static electricity is generated in the display panel, the conductive pads 310 that are closer to the display panel can discharge the static electricity in time, thereby improving the static electricity protection effect of the display panel.

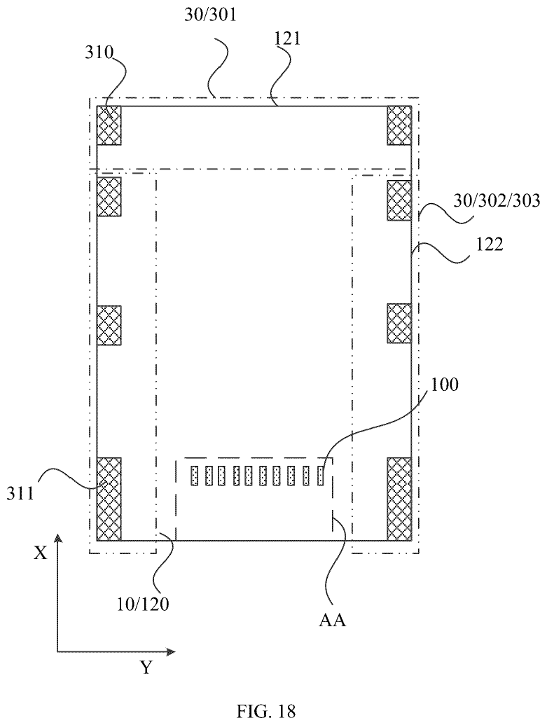

FIG. 18 is a structural schematic view of a second main surface of a substrate according to yet another embodiment of the present application. Referring to FIG. 18, the second main surface 120 further includes a drive pad setting region AA including a plurality of drive pads 100. The plurality of the conductive pad setting regions 30 include a third conductive pad setting region 303 extending along a first direction X, and the drive pad setting region AA extends along a second direction Y intersecting the first direction X. The conductive pad 310 in the third conductive pad setting region 303 includes a first conductive pad 311, and the first conductive pad 311 at least partially overlaps the drive pad setting region AA in the second direction Y. The length of the first conductive pad 311 is the same as that of the drive pad setting region AA in the first direction X.

In the embodiment shown in FIG. 18, the extending direction of the third conductive pad setting region 303 intersects that of the driving pad setting region AA, and an overlapping area is provided between the third conductive pad setting region 303 and the driving pad setting region AA in the second direction Y. Furthermore, the length of the first conductive pad 311 in the overlapping area is the same as the length of the driving pad setting region AA. On one hand, the surface area of the first conductive pad 311 can be increased to improve the electrostatic discharge speed. On the other hand, when forming the first conductive pad 311 and the driving pad setting region AA, the entire surface of the second main surface 120 is usually evaporated first, and then the unnecessary parts are deducted to form the first conductive pad 311 and the driving pad setting region AA. In this way, the length of the first conductive pad 311 is the same as the length of the driving pad setting region AA, the deduction time can be saved when forming the first conductive pad 311, thereby saving the process time.

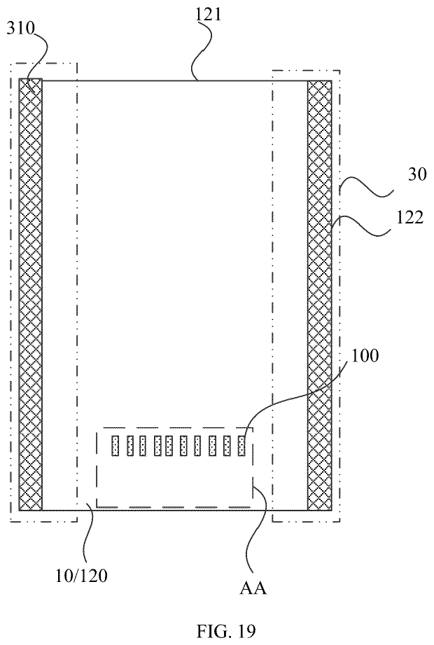

In another embodiment, FIG. 19 is a structural schematic view of a second main surface of a substrate according to still yet another embodiment of the present application. Referring to FIG. 19, the conductive pad setting region 30 includes a conductive pad 310, the length of which is the same as that of the side of the second main surface 120 corresponding to the conductive pad setting region 30.

In embodiments shown in FIG. 19, the conductive pad 310 can be disposed on the entire surface, that is, the length of the conductive pad 310 is the same as the length of the side of the second main surface 120 corresponding to the conductive pad setting region 30. On the one hand, the surface area of the first conductive pad 311 can be further increased, greatly improving the electrostatic discharge speed of the first conductive pad 311; on the other hand, the deduction time for forming the conductive pad 310 is further saved, thereby saving process time.

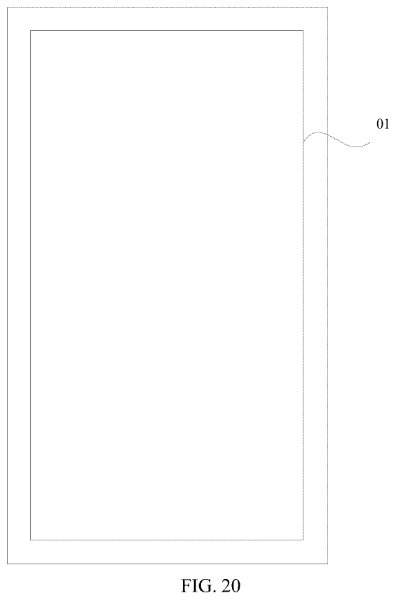

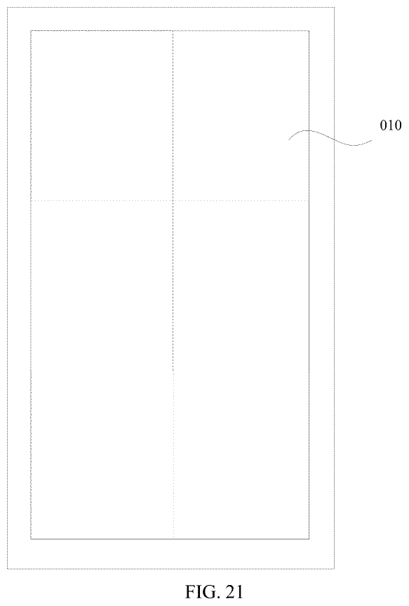

The embodiments of the present application further provides a display device. FIG. 20 is a structural schematic view of a display apparatus according to still yet another embodiment of the present application. As shown in FIG. 20, the display device includes any of the display modules 01 described in the above embodiments. Therefore, the display device provided in embodiments of the present application has the corresponding beneficial effects of the display module 01 provided in the embodiment of the present application which will not be repeated here. Exemplarily, the display device can be an electronic device such as a mobile phone, a computer, a smart wearable device (for example, a smart watch), and a vehicle-mounted display device. In addition, in other embodiments, FIG. 21 is a structural schematic view of a display apparatus according to another embodiment of the present application. As shown in FIG. 21, the display device can further be a spliced display device which is formed by splicing a plurality of display panels 101.

What is claimed is:

1. A display module comprising a display panel which comprises:
a substrate comprising a first main surface, and a second main surface opposite to the first main surface;
an electrostatic structure disposed on the first main surface; and
at least one conductive pad setting region disposed on the second main surface and comprising at least one conductive pad coupled to the electrostatic structure.

2. The display module according to claim 1, wherein the at least one conductive pad is electrically connected to a fixed terminal; or
the conductive pad includes a ground pad.

3. The display module according to claim 1, wherein the electrostatic structure comprises a plurality of electrostatic structure subsections spaced apart, and the length of the electrostatic structure subsection is M1 along an extending direction of the electrostatic structure subsection;
wherein the first main surface comprises a first side and a second side, the length of the first side is greater than that of the second side, and the length of the second side is N1, where M1>N1/2; or
wherein the first main surface comprises a first side and a second side, and an extending direction of the first side intersects the extending direction of the second side;
wherein the electrostatic structure comprises a first electrostatic structure subsection and a second electrostatic structure subsection electrically connected to the first electrostatic structure subsection, an extending direction of the first electrostatic structure subsection is the same as that of the first side, and an extending direction of the second electrostatic structure subsection is the same as that of the second side.

4. The display module according to claim 1, further comprising at least one conductive bracket structure fixed on the second main surface, electrically connected to the conductive pad, and at least partially overlapping the display panel in a thickness direction of the display panel.

5. The display module according to claim 4, wherein the second main surface comprises a driving pad setting region which comprises a plurality of driving pads;
wherein the conductive bracket structure comprises a conductive bracket body at least partially overlapping the conductive pad in the thickness direction of the display panel, and a hollow area at least partially overlapping the driving pad setting region in the thickness direction of the display panel.

6. The display module according to claim 4, wherein a plurality of the conductive bracket structures are independently spaced apart; or the plurality of the conductive bracket structures are formed integrally.

7. The display module according to claim 4, further comprising:
a plurality of display panels;
a conductive splicing frame disposed on a side of the conductive bracket structure facing away from the display panel; and
a plurality of printed circuit boards electrically connected to the conductive splicing frame and the conductive bracket structure fixed to the display panels and the conductive splicing frame, respectively,
wherein a plurality of accommodating spaces are formed between the conductive splicing frame and the conductive bracket structure, and the printed circuit boards are disposed in the accommodating spaces.

8. The display module according to claim 7, wherein the printed circuit boards comprises:
a first printed circuit board disposed on a side of the accommodation space close to the conductive bracket structure, and fixed and electrically connected to the conductive bracket structure; and
a second printed circuit board disposed on a side of the accommodation space close to the conductive splicing frame, fixed and electrically connected to the conductive splicing frame, and electrically connected to the first printed circuit board.

9. The display module according to claim 8, further comprising a plurality of retractable probes,
wherein the first printed circuit board comprises a first surface facing away from the conductive bracket structure, the first surface being provided with a plurality of first pads; and
the second printed circuit board comprises a second surface facing away from the conductive splicing frame, the second surface being provided with a plurality of second pads that are electrically connected to the first pads through the retractable probes.

10. The display module according to claim 7, further comprising a plurality of magnet structures, and the conductive bracket structure is detachably fixedly connected to the conductive splicing frame though the magnet structures.

11. The display module according to claim 1, further comprising a light-transmitting conductive layer disposed on the first main surface and coupled to the conductive pad.

12. The display module according to claim 1, wherein the substrate further comprises a plurality of side surfaces connecting the first main surface and the second main surface, and is provided with at least one side wiring electrically connected to the electrostatic structure and the conductive pad.

13. The display module according to claim 12, wherein the side surface is provided with a side wiring, the line width of which is D1, and a width of a long side of the side surface is D2, where D1>D2/2; or
the side surface is provided with at least two side wirings spaced apart.

14. The display module according to claim 12, wherein the side surface comprises a first chamfered subsection, a second chamfered subsection, and a planar portion, the first chamfered subsection being connected to the first main surface and the planar portion, the planar portion being connected to the first chamfered subsection and the second chamfered subsection, and the second chamfered subsection being connected to the planar portion and the second main surface;
wherein the side wiring includes a first side wiring subsection disposed at the first chamfered subsection and electrically connected to the electrostatic structure, a second side wiring subsection disposed at the second chamfered subsection and electrically connected to the conductive pad, and a plurality of third side wiring subsections disposed at the plane portion and electrically connected to the first side wiring subsection and the second side wiring subsection;
wherein the third side wiring subsections comprises a first subsection disposed in a region of the third side wiring subsection close to the first side wiring subsection, a second subsection, and a third subsection disposed in a region of the third side wiring subsection close to the second side wiring subsection, the second subsection connecting the first subsection and the third subsection; and
the line widths of any two of the first subsection, the second subsection, and the third subsection are the same; or
wherein the third side wiring subsections comprises a first subsection disposed in a region of the third side wiring subsection close to the first side wiring subsection, a second subsection, and a third subsection disposed in a region of the third side wiring subsection close to the second side wiring subsection, the second subsection connecting the first subsection and the third subsection; and
a line width of each of the first subsection and the third subsection are greater than that of the second subsection.

15. The display module according to claim 1, wherein the substrate is provided with a via, and the electrostatic structure is electrically connected to the conductive pad through the via.

16. The display module according to claim 1, wherein the substrate further comprises a plurality of side surfaces connecting the first main surface and the second main surface comprising a plurality of conductive pad setting regions, the conductive pad setting regions being disposed in the edge area of the second main surface close to the side surfaces, and disposed on different sides of the second main surface.

17. The display module according to claim 16, wherein the conductive pad setting region comprises a plurality of conductive pads comprising a first conductive pad setting region and a second conductive pad setting region;
wherein the second main surface comprises a third side and a fourth side, and the length of the fourth side is greater than that of the third side, the first conductive pad setting region being disposed on the second main surface close to the third side, and the second conductive pad setting region being disposed on the second main surface close to the fourth side;
wherein the number of conductive pads in the second conductive pad setting region is greater than that in the first conductive pad setting region; or
wherein the conductive pad setting region comprises a plurality of conductive pads comprising a first conductive pad setting region and a second conductive pad setting region;
wherein the second main surface comprises a third side and a fourth side, and the length of the fourth side is greater than that of the third side, the first conductive pad setting region being disposed on the second main surface close to the third side, and the second conductive pad setting region being disposed on the second main surface close to the fourth side;
an arrangement density of the conductive pads in the second conductive pad setting region is greater than that in the first pad setting region.

18. The display module according to claim 16, wherein the second main surface further comprises a drive pad setting region comprising a plurality of drive pads and extending along a first direction;
wherein the plurality of the conductive pad setting regions comprises a third conductive pad setting region extending along a second direction intersecting the first direction, the conductive pad in the third conductive pad setting region comprises a first conductive pad at least partially overlapping the drive pad setting region in the first direction, and a length of the first conductive pad is the same as that of the drive pad setting region in the second direction.

19. The display module according to claim 1, wherein the conductive pad setting region comprises one conductive pad, the length of the conductive pad is the same as that of a side of the second main surface corresponding to the conductive pad setting region; or
wherein the conductive pad setting region comprises a plurality of the conductive pads evenly spaced in an extending direction of the conductive pad setting region.

20. A display apparatus comprising a display module which comprise a display panel comprising:
a substrate comprising a first main surface, and a second main surface opposite to the first main surface;
an electrostatic structure disposed on the first main surface; and
at least one conductive pad setting region disposed on the second main surface and comprising at least one conductive pad coupled to the electrostatic structure.
